(19) United States
(12) Patent Application Publication
(10) Pub. No.: US 2025/0087568 A1
(43) Pub. Date: Mar. 13, 2025

(54) MULTILAYER SUBSTRATE

(71) Applicant: Murata Manufacturing Co., Ltd., Nagaokakyo-shi (JP)

(72) Inventors: Issei YAMAMOTO, Nagaokakyo-shi (JP); Tomoki YAMAMOTO, Nagaokakyo-shi (JP)

(21) Appl. No.: 18/960,244

(22) Filed: Nov. 26, 2024

Related U.S. Application Data
(63) Continuation of application No. PCT/JP2023/018392, filed on May 17, 2023.

(30) Foreign Application Priority Data
Jun. 1, 2022 (JP) 2022-089630

(51) Int. Cl. H01L 23/498

(52) U.S. Cl. CPC H01L 23/49822; H01L 23/49838; H01L 23/49894

(57) ABSTRACT

A multilayer substrate that includes: a first thermoplastic resin layer including a first main surface, a second main surface opposite to the first main surface, and a via hole penetrating from the first main surface to the second main surface; a ceramic layer in contact with the first main surface; a second thermoplastic resin layer in contact with the second main surface; a first electrode on a surface of the ceramic layer in contact with the first main surface; a protective layer covering at least part of an outline of the first electrode; a second electrode on a surface of the second thermoplastic resin layer in contact with the second main surface; an interlayer connection conductor in the via hole and connecting the first electrode and the second electrode; and an intermetallic compound between the interlayer connection conductor and the first electrode.

### CROSS REFERENCE TO RELATED APPLICATIONS

The present application is a continuation of International application No. PCT/JP2023/018392, filed May 17, 2023, which claims priority to Japanese Patent Application No. 2022-089630, filed Jun. 1, 2022, the entire contents of each of which are incorporated herein by reference.

### TECHNICAL FIELD

The present disclosure relates to a multilayer substrate.

### BACKGROUND ART

Conventionally, modular components using multilayer substrates with built-in passive elements have been put to practical use. For example, a DC-DC converter module is known in which a switching integrated circuit (IC) chip and a chip capacitor are mounted on a multilayer substrate with a built-in coil as a passive element.

Known multilayer substrates used for such module components include a multilayer substrate in which ceramic substrates are laminated. In a multilayer substrate in which ceramic substrates are laminated, any of the ceramic substrates may peel off. In order to solve such a problem, Patent Literature 1 discloses a multilayer substrate (module component) in which a substrate made of a thermoplastic resin (thermoplastic resin layer) is laminated on a multiple-layer substrate in which ceramic substrates are laminated.

In other words, Patent Literature 1 discloses a module component including: a ceramic multilayer substrate with a built-in passive component, a first terminal electrode on one main surface of the ceramic multilayer substrate, and a second terminal electrode on the other surface thereof, the first terminal electrode and the second terminal electrode being connected to the passive component; a first thermoplastic resin layer on the one main surface of the ceramic multilayer substrate, the first thermoplastic resin layer including a first wire connected to the first terminal electrode and a first land for mounting a surface-mounted component thereon; a second thermoplastic layer on the other main surface of the ceramic multilayer substrate, the second thermoplastic layer including a second wire connected to the second terminal electrode and a second land serving as a connection terminal to a mother board; and a surface-mounted component mounted on the first thermoplastic resin layer and connected to the first land of the first thermoplastic resin layer. The first thermoplastic resin layer and the second thermoplastic resin layer have different thicknesses, the first thermoplastic resin layer is thicker than the second thermoplastic resin layer, the ceramic multilayer substrate is a substrate including a non-glass-based low-temperature co-fired ceramic material, the first terminal electrode of the ceramic multilayer substrate and an interlayer conductor in the first thermoplastic resin layer are bonded by transient liquid phase diffusion bonding, and the second terminal electrode of the ceramic multilayer substrate and an interlayer conductor in the second thermoplastic resin layer are bonded by transient liquid phase diffusion bonding.

In Patent Literature 1, the terminal electrodes in the ceramic multilayer substrate and the interlayer conductors in the thermoplastic resin layers are bonded by transient liquid phase diffusion bonding.

Patent Literature 2 discloses an interlayer connection conductor connected to a conductive wiring layer. An intermetallic compound layer including an intermetallic compound is formed between the conductive wiring layer and the interlayer connection conductor.

The intermetallic compound layer is produced in such a way that a metal such as Sn or an Sn alloy of the interlayer connection conductor melts when heated and reacts with a metal (e.g., Cu) of the conductive wiring layer. In other words, the intermetallic compound layer is produced when transient liquid phase diffusion bonding occurs.
Patent Literature 1: JP 6819668 B
Patent Literature 2: WO 2019/003729

### SUMMARY OF THE DISCLOSURE

The multilayer substrate (module component) described in Patent Literature 1 also includes an intermetallic compound layer as disclosed in Patent Literature 2 between the electrode (terminal electrode) on the ceramic layer and the interlayer connection conductor (interlayer conductor) in the thermoplastic resin layer.

The linear thermal expansion coefficient of the ceramic layer is different from the linear thermal expansion coefficient of the thermoplastic resin layer. Thus, when heat is applied to the multilayer substrate, thermal stress occurs between the ceramic layer and the thermoplastic resin layer.

Such thermal stress is likely to be applied to the interlayer connection conductor located at the boundary between the ceramic layer and the thermoplastic resin layer. In particular, thermal stress is more likely to be applied to the connection portion between the interlayer connection conductor and the electrode on the ceramic layer.

As described above, an intermetallic compound layer is formed between the electrode on the ceramic layer and the interlayer connection conductor in the thermoplastic resin layer. An intermetallic compound has low ductility and is thus less likely to absorb thermal stress.

Therefore, when the interlayer connection conductor is subjected to the thermal stress, cracking and peeling are likely to occur starting from the intermetallic compound and the interlayer connection conductor surrounding the intermetallic compound.

The present disclosure has been made to solve the above problems, and an object of the present disclosure is to provide a multilayer substrate in which cracking and peeling are less likely to occur at a connection portion between an electrode on a ceramic layer and an interlayer connection conductor in a thermoplastic resin layer, even when thermal stress occurs.

A multilayer substrate of the present disclosure includes: a first thermoplastic resin layer including a first main surface, a second main surface opposite to the first main surface, and a via hole penetrating from the first main surface to the second main surface; a ceramic layer in contact with the first main surface of the first thermoplastic resin layer; a second thermoplastic resin layer in contact with the second main surface of the first thermoplastic resin layer; a first electrode on a surface of the ceramic layer in contact with the first main surface of the first thermoplastic resin layer; a protective layer covering at least part of an outline of the first electrode; a second electrode on a surface of the second thermoplastic resin layer in contact with the second main surface of the first thermoplastic resin layer; an interlayer connection conductor in the via hole and connecting the first electrode and the second electrode; and an intermetallic compound between the interlayer connection conductor and the first electrode.

The present disclosure provides a multilayer substrate in which cracking and peeling are less likely to occur at a connection portion between an electrode on a ceramic layer and an interlayer connection conductor in a thermoplastic resin layer, even when thermal stress occurs.

### BRIEF DESCRIPTION OF THE DRAWINGS

FIG. 1A is a schematic cross-sectional view of an example of a multilayer substrate according to a first embodiment of the present disclosure.

FIG. 1B is an enlarged view of a dashed line area in FIG. 1A.

FIG. 2 is a schematic cross-sectional view of an example of an interlayer connection conductor and its surroundings of a multilayer substrate according to a second embodiment of the present disclosure.

FIG. 3 is a schematic cross-sectional view of an example of an interlayer connection conductor and its surroundings of another multilayer substrate according to the second embodiment of the present disclosure.

FIG. 4 is a schematic cross-sectional view of an example of an interlayer connection conductor and its surroundings of a multilayer substrate according to a third embodiment of the present disclosure.

FIG. 5 is a schematic cross-sectional view of an example of an interlayer connection conductor and its surroundings of a multilayer substrate according to a fourth embodiment of the present disclosure.

FIG. 6 is a schematic cross-sectional view of an example of an interlayer connection conductor and its surroundings of a multilayer substrate according to another embodiment of the present disclosure.

FIG. 7 is a schematic process diagram of an example of preparing LTCC green sheets in a method of producing a multilayer substrate according to a fifth embodiment of the present disclosure.

FIG. 8A is a schematic process diagram of an example of filling via holes of the LTCC green sheets in the method of producing the multilayer substrate according to the fifth embodiment of the present disclosure.

FIG. 8B is a schematic process diagram of an example of filling the via holes of the LTCC green sheets in the method of producing the multilayer substrate according to the fifth embodiment of the present disclosure.

FIG. 9 is a schematic process diagram of an example of forming electrode patterns on the LTCC green sheets in the method of producing the multilayer substrate according to the fifth embodiment of the present disclosure.

FIG. 10 is a schematic process diagram of an example of applying a protective layer paste containing a ceramic material in the method of producing the multilayer substrate according to the fifth embodiment of the present disclosure.

FIG. 11 is a schematic process diagram of an example of laminating the LTCC green sheets in the method of producing the multilayer substrate according to the fifth embodiment of the present disclosure.

FIG. 12 is a schematic process diagram of an example of firing an LTCC green sheet laminate in the method of producing the multilayer substrate according to the fifth embodiment of the present disclosure.

FIG. 13 is a schematic process diagram of an example of preparing thermoplastic resin layers in the method of producing the multilayer substrate according to the fifth embodiment of the present disclosure.

FIG. 14A is a schematic process diagram of an example of forming electrode patterns on the thermoplastic resin layers in the method of producing the multilayer substrate according to the fifth embodiment of the present disclosure.

FIG. 14B is a schematic process diagram of an example of forming the electrode patterns on the thermoplastic resin layers in the method of producing the multilayer substrate according to the fifth embodiment of the present disclosure.

FIG. 15A is a schematic process diagram of an example of filling via holes of the thermoplastic resin layers in the method of producing the multilayer substrate according to the fifth embodiment of the present disclosure.

FIG. 15B is a schematic process diagram of an example of filling the via holes of the thermoplastic resin layers in the method of producing the multilayer substrate according to the fifth embodiment of the present disclosure.

FIG. 16 is a schematic process diagram of an example of laminating the thermoplastic resin layers in the method of producing the multilayer substrate according to the fifth embodiment of the present disclosure.

FIG. 17A is a schematic process diagram of an example of laminating a multilayer ceramic layer and a multilayer thermoplastic resin layer in the method of producing the multilayer substrate according to the fifth embodiment of the present disclosure.

FIG. 17B is a schematic process diagram of an example of laminating the multilayer ceramic layer and the multilayer thermoplastic resin layer in the method of producing the multilayer substrate according to the fifth embodiment of the present disclosure.

FIG. 18A is an explanatory schematic diagram of an example of connection between an interlayer connection conductor and a first electrode by transient liquid phase diffusion bonding.

FIG. 18B is an explanatory schematic diagram of an example of the connection between the interlayer connection conductor and the first electrode by transient liquid phase diffusion bonding.

FIG. 18C is an explanatory schematic diagram of an example of the connection between the interlayer connection conductor and the first electrode by transient liquid phase diffusion bonding.

FIG. 18D is an explanatory schematic diagram of an example of the connection between the interlayer connection conductor and the first electrode by transient liquid phase diffusion bonding.

FIG. 19 is a schematic cross-sectional view of an example of a multilayer ceramic layer prepared in a method of producing a multilayer substrate according to a sixth embodiment of the present disclosure.

FIG. 20 is a schematic cross-sectional view of an example of a multilayer thermoplastic resin layer prepared in the method of producing the multilayer substrate according to the sixth embodiment of the present disclosure.

FIG. 21 is a schematic process diagram of an example of disposing protective layers including a thermoplastic resin in the method of producing the multilayer substrate according to the sixth embodiment of the present disclosure.

FIG. 22A is a schematic process diagram of an example of laminating a multilayer ceramic layer and a multilayer thermoplastic resin layer in the method of producing the multilayer substrate according to the sixth embodiment of the present disclosure.

FIG. 22B is a schematic process diagram of an example of laminating the multilayer ceramic layer and the multilayer thermoplastic resin layer in the method of producing the multilayer substrate according to the sixth embodiment of the present disclosure.

### DESCRIPTION OF THE PREFERRED EMBODIMENTS

Hereinafter, a multilayer substrate of the present disclosure is described.

The present disclosure is not limited to the following preferred embodiments, and may be suitably modified without departing from the gist of the present disclosure. Combinations of two or more preferred features described in the following preferred embodiments are also within the scope of the present disclosure.

A multilayer substrate of the present disclosure includes: a first thermoplastic resin layer including a first main surface, a second main surface opposite to the first main surface, and a via hole penetrating from the first main surface to the second main surface; a ceramic layer in contact with the first main surface of the first thermoplastic resin layer; a second thermoplastic resin layer in contact with the second main surface of the first thermoplastic resin layer; a first electrode on a surface of the ceramic layer in contact with the first main surface of the first thermoplastic resin layer; a protective layer covering at least part of an outline of the first electrode; a second electrode on a surface of the second thermoplastic resin layer in contact with the second main surface of the first thermoplastic resin layer; an interlayer connection conductor in the via hole and connecting the first electrode and the second electrode; and an intermetallic compound between the interlayer connection conductor and the first electrode.

In other words, in the multilayer substrate of the present disclosure, the protective layer covers at least part of the outline of the first electrode. Such a protective layer can prevent the spread and formation of an intermetallic compound with low ductility at the connection portion between the interlayer connection conductor and the first electrode.

Thus, even when thermal stress occurs in the multilayer substrate, the area where the thermal stress is difficult to relax is small, because the area where the intermetallic compound is formed is small.

As a result, even when thermal stress occurs in the multilayer substrate, cracking and peeling are less likely to occur at the connection portion between the electrode on the ceramic layer and the interlayer connection conductor in the thermoplastic resin layer.

The multilayer substrate of the present disclosure can be widely used in electronic devices such as portable information terminals and digital cameras as a multilayer substrate with a built-in coil and/or as a multilayer substrate in a micro DC-DC converter.

The following describes embodiments of the multilayer substrate of the present disclosure with reference to drawings.

### First Embodiment

First, a multilayer substrate according to a first embodiment of the present disclosure is described.

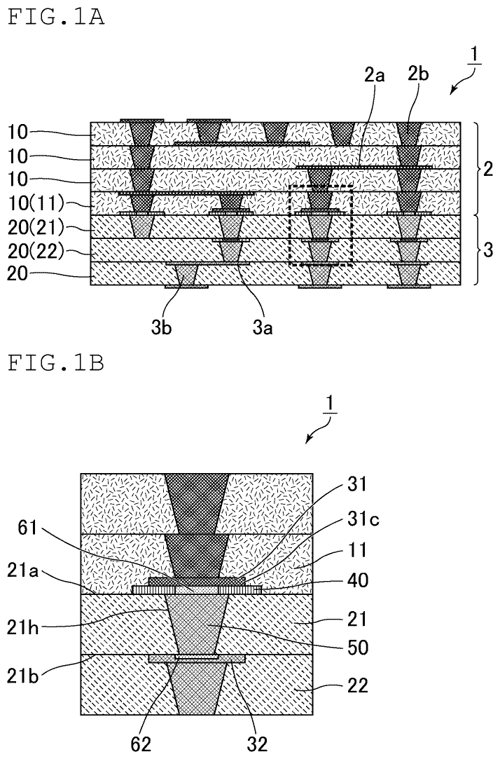

FIG. 1A is a schematic cross-sectional view of an example of the multilayer substrate according to the first embodiment of the present disclosure.

FIG. 1B is an enlarged view of a dashed line area in FIG. 1A.

A multilayer substrate 1 shown in FIG. 1A includes a multilayer ceramic layer 2 including a laminate of multiple ceramic layers 10 and a multilayer thermoplastic resin layer 3 including a laminate of multiple thermoplastic resin layers 20.

In the multilayer substrate 1 shown in FIG. 1A, the multilayer ceramic layer 2 is laminated on the multilayer thermoplastic resin layer 3.

As shown in FIG. 1A and FIG. 1B, the multilayer thermoplastic resin layer 3 includes a first thermoplastic resin layer 21 in contact with the multilayer ceramic layer 2.

As shown in FIG. 1B, the first thermoplastic resin layer 21 has a first main surface 21a, a second main surface 21b opposite to the first main surface 21a, and a via hole 21h penetrating from the first main surface 21a to the second main surface 21b.

The first main surface 21a of the first thermoplastic resin layer 21 is in contact with the multilayer ceramic layer 2.

The multilayer ceramic layer 2 includes a ceramic layer 11 in contact with the first main surface 21a of the first thermoplastic resin layer 21. A first electrode 31 is formed on a main surface of the ceramic layer 11 in contact with the first main surface 21a, and a protective layer 40 covers an outline 31c of the first electrode 31.

In the multilayer substrate of the present disclosure, the protective layer may cover the entire outline of the first electrode, or may cover part of the outline of the first electrode.

The multilayer thermoplastic resin layer 3 includes a second thermoplastic resin layer 22 in contact with the second main surface 21b.

A second electrode 32 is formed on a main surface of the second thermoplastic resin layer 22 in contact with the second main surface 21b.

An interlayer connection conductor 50 connecting the first electrode 31 and the second electrode 32 is disposed in the via hole 21h. An intermetallic compound 61 is formed between the interlayer connection conductor 50 and the first electrode 31. An intermetallic compound 62 is formed between the interlayer connection conductor 50 and the second electrode 32.

The via hole 21h has a tapered shape in which the opening in the first main surface 21a is larger than the opening in the second main surface 21b.

The via hole 21h having such a shape can improve the connection strength between the interlayer connection conductor 50 and the first electrode 31.

In the multilayer substrate 1, the protective layer 40 covers the outline 31c of the first electrode 31. Such a protective layer 40 can prevent the spread and formation of the intermetallic compound 61, which has low ductility, at the connection portion between the interlayer connection conductor 50 and the first electrode 31. The intermetallic compound 61 has low ductility and serves as a portion where thermal stress is difficult to relax.

In the multilayer substrate 1, the area where the thermal stress is difficult to relax is small, because the area where the intermetallic compound 61 is formed is small.

Therefore, even when thermal stress occurs in the multilayer substrate 1, cracking and peeling are less likely to occur at the connection portion between the first electrode 31 on the ceramic layer 11 and the interlayer connection conductor 50 in the first thermoplastic resin layer 21.

As shown in FIG. 1A and FIG. 1B, in the multilayer substrate 1, part of the protective layer 40 is inside the opening of the via hole 21h in the first main surface 21a. The part of the protective layer 40 inside the opening of the via hole 21h is in contact with the interlayer connection conductor 50.

In the production of the multilayer substrate 1, the via hole 21h is filled with a conductive paste, then the conductive paste is brought into contact with the first electrode 31, and the conductive paste is melted and then solidified to form the interlayer connection conductor 50.

When the multilayer substrate 1 has the above-described structure, the opening of the via hole 21h in the first main surface 21a is large, which can achieve a sufficient contact between the conductive paste and an exposed surface of the first electrode 31. Thereby, the electrical connection reliability can be improved.

As shown in FIG. 1A, the multilayer ceramic layer 2 may include electrode patterns 2a, vias 2b, etc., and the multilayer thermoplastic resin layer 3 may include electrode patterns 3a, vias 3b, etc.

The following describes preferred forms of the components of the multilayer substrate 1.

### Interlayer Connection Conductor

The interlayer connection conductor 50 is formed by filling the via hole 21h with a conductive paste containing a first metal powder and a second metal powder having a higher melting point than the first metal powder, and melting the conductive paste, followed by solidifying. The first metal powder in the conductive paste reacts with the first electrode 31 to form the intermetallic compound 61.

Preferably, the first metal powder is made of Sn or a Sn alloy and the second metal powder is made of a Cu—Ni alloy or a Cu—Mn alloy.

The conductive paste is specifically described in the section <Method of producing multilayer substrate> described below.

### Multilayer Ceramic Layer

The multilayer ceramic layer 2 includes the ceramic layers 10 including the ceramic layer 11.

The ceramic layers 10 may be made of, for example, a low temperature co-fired ceramic (LTCC) material. The low temperature co-fired ceramic material is a ceramic material that can be fired at a temperature of 1000° C. or lower and that can be co-fired with a low-resistive material such as Au, Ag, or Cu. Specific examples of the low temperature co-fired ceramic material include glass composite low temperature co-fired ceramic materials obtained by mixing a ceramic powder of alumina, zirconia, magnesia, forsterite, or the like with borosilicate glass; crystallized glass low temperature co-fired ceramic materials containing ZnO—MgO—Al₂O₃—SiO₂ crystallized glass; and non-glass low temperature co-fired ceramic materials containing BaO—Al₂O₃—SiO₂ ceramic powder, Al₂O₃—CaO—Sio₂—MgO—B₂O₃ ceramic powder, or the like.

The thickness of the ceramic layer 10 is preferably determined appropriately according to the design of the multilayer substrate, and is preferably, for example, 5 μm to 100 μm.

Preferably, the first electrodes 31, the electrode patterns 2a, and the vias 2b are fired bodies of a conductive paste including a conductive powder, a plasticizer, and a binder.

More preferably, the first electrodes 31, the electrode patterns 2a, and the vias 2b are fired bodies of copper (Cu) or an alloy thereof.

The first electrodes 31, the electrode patterns 2a, and the vias 2b may contain silver (Ag), aluminum (Al), nickel (Ni), stainless steel (SUS), gold (Au), an alloy of any of these, or the like.

The first electrodes 31, the electrode patterns 2a, and the vias 2b may be made of the same material or different materials.

The thickness of the first electrode 31 is preferably determined appropriately according to the design of the multilayer substrate, and is preferably, for example, 3 μm to 40 μm. Herein, the “thickness of the first electrode” refers to the maximum thickness of the first electrode.

### Protective Layer

The protective layer 40 may be made of the same material as the material of the first thermoplastic resin layer 21 or may be made of the same material as the material of the ceramic layer 11.

The thickness of the protective layer 40 is preferably 2 μm to 10 μm.

If the thickness of the protective layer is less than 2 μm, the first electrode is likely to peel off.

If the thickness of the protective layer is more than 10 μm, the protective layer hinders the lamination of the first thermoplastic resin layer and the ceramic layer. As a result, a gap occurs between the interlayer connection conductor and the first electrode, preventing connection therebetween. Also, the internal conductors such as the first electrodes, the electrode patterns, and the vias easily deform.

The protective layer 40 preferably covers an area of 30 μm to 100 μm inward from the outline of the first electrode 31.

The formation of the protective layer 40 in such an area can prevent peeling off of the first electrode 31.

### Multilayer Thermoplastic Resin Layer

The multilayer thermoplastic resin layer 3 includes the thermoplastic resin layers 20 including the first thermoplastic resin layer 21 and the second thermoplastic resin layer 22.

Examples of materials of the thermoplastic resin layer 20 include liquid crystal polymers (LCP), thermoplastic polyimide resins, polyether ether ketone (PEEK) resins, and polyphenylene sulfide (PPS) resins.

Of these, liquid crystal polymers (LCP) are preferred. Liquid crystal polymers have a lower water absorption rate than other thermoplastic resins, and can prevent variations in electrical characteristics and deterioration in electrical connection reliability.

The thickness of the thermoplastic resin layer 20 is preferably determined appropriately according to the design of the multilayer substrate, and is preferably, for example, 10 μm to 100 μm.

As shown in FIG. 1B, the via hole 21h in the first thermoplastic resin layer 21 has a tapered shape.

Preferably, the tapered shape has an inclination angle that changes stepwise. In this case, the inclination angle may change in two steps, or three or more steps.

In the multilayer substrate of the present disclosure, each via hole may have a tapered shape in which the opening in the first main surface is smaller than the opening in the second main surface, or may have a cylindrical shape in which the opening in the first main surface and the opening in the second main surface have the same size.

The opening of the via hole 21h in the first main surface 21a preferably has a diameter of 20 μm to 200 μm.

The opening of the via hole 21h in the second main surface 21b preferably has a diameter of 20 μm to 200 μm.

In the multilayer substrate 1 shown in FIG. 1B, the area of the first electrode 31 (the area in contact with the intermetallic compound 61 and the protective layer 40) is larger than the area of the opening of the via hole 21h in the first main surface 21a. In the multilayer substrate 1 of the present disclosure, the area of the first electrode and the area of the opening of the via hole in the first main surface may be the same, or the area of the first electrode may be smaller than the area of the opening of the via hole in the first main surface.

Examples of materials of the second electrodes 32 and the electrode patterns 3a include copper (Cu), silver (Ag), aluminum (Al), nickel (Ni), stainless steel (SUS), and alloys thereof. The second electrodes 32 and the electrode patterns 3a can be formed by laminating a metal foil on the thermoplastic resin layer 20 and patterning it by a technique such as etching.

The second electrodes 32 and the electrode patterns 3a may be made of the same material or different materials.

Preferred materials of the vias 2b are the same as the preferred materials of the interlayer connection conductors 50.

The thickness of the second electrode 32 is preferably determined appropriately according to the design of the multilayer substrate, and is preferably, for example, 3 μm to 40 μm.

### Second Embodiment

Next, a multilayer substrate according to a second embodiment of the present disclosure is described.

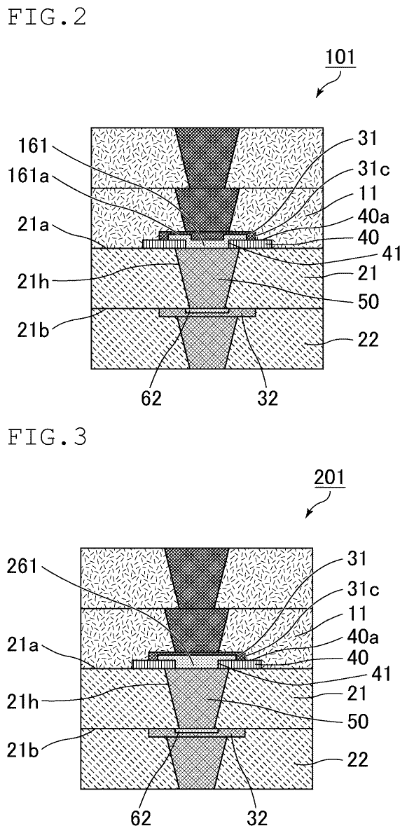

FIG. 2 is a schematic cross-sectional view of an example of an interlayer connection conductor and its surroundings of the multilayer substrate according to the second embodiment of the present disclosure.

A multilayer substrate 101 according to the second embodiment of the present disclosure shown in FIG. 2 has the same structure as the multilayer substrate 1 according to the first embodiment, except for the shape of the intermetallic compound.

The structure of the multilayer substrate 101 is described in detail below with reference to the drawings.

As shown in FIG. 2, an end of the protective layer 40 inside the outline of the first electrode 31 is defined as an inner end 41, and a main surface of the protective layer 40 in contact with the first electrode 31 to cover the outline of the first electrode 31 is defined as a covering surface 40a.

In the multilayer substrate 101, part 161a of an intermetallic compound 161 is in contact with an inner end 41 side area of the covering surface 40a of the protective layer 40 and is continuous with the intermetallic compound 161 formed between the interlayer connection conductor 50 and the first electrode 31.

In other words, the part 161a of the intermetallic compound 161 interposes between the protective layer 40 and the first electrode 31.

The shape of the intermetallic compound 161 in FIG. 2 is such that a portion in contact with the covering surface 40a of the protective layer 40 (i.e., the portion indicated by the symbol 161a) is raised higher than the other portion.

In the production of the multilayer substrate of the present disclosure, the first electrode is brought into contact with a conductive paste that is a precursor of the interlayer connection conductor, and the conductive paste is melted and then solidified to form the interlayer connection conductor.

In this case, when the protective layer is formed at the outline of the first electrode, an exposed surface of the first electrode (the surface in contact with the conductive paste) is small.

In the multilayer substrate produced, the physical connection stability and electrical conductivity between the first electrode and the interlayer connection conductor depend on the contact area therebetween through the intermetallic compound. Therefore, the formation of the protective layer at the outline of the first electrode is disadvantageous in achieving these properties.

However, in the multilayer substrate 101 in which the part 161a of the intermetallic compound 161 is in contact with the inner end 41 side area of the covering surface 40a of the protective layer 40 and is continuous with the intermetallic compound 161 formed between the interlayer connection conductor 50 and the first electrode 31, the contact area between the first electrode 31 and the intermetallic compound 161 can be increased. Therefore, the physical connection stability and electrical conductivity between the first electrode 31 and the interlayer connection conductor 50 can be improved.

The thickness of the first electrode 31 in the multilayer substrate 101 is preferably determined appropriately according to the design, and is preferably, for example, 3 μm to 40 μm. In the multilayer substrate 101, a portion of the first electrode 31 in contact with the part 161a of the intermetallic compound 161 has a small thickness.

As described above, the phrase “thickness of the first electrode” herein means the maximum thickness of the first electrode. Thus, in the measurement of the “thickness of the first electrode”, such a portion having a small thickness is not taken into consideration.

In the multilayer substrate 101, the thickness of the protective layer 40 is preferably 2 μm to 10 μm.

If the thickness of the protective layer is less than 2 μm, the first electrode is likely to peel off.

If the thickness of the protective layer is more than 10 μm, the liquid phase in transient liquid phase diffusion bonding is less likely to flow over the protective layer in the formation of the intermetallic compound, and the intermetallic compound is less likely to be in contact with an inner end side area of the covering surface of the protective layer.

Next, another multilayer substrate according to the second embodiment of the present disclosure is described.

FIG. 3 is a schematic cross-sectional view of an example of an interlayer connection conductor and its surroundings of another multilayer substrate according to the second embodiment of the present disclosure.

A multilayer substrate 201 shown in FIG. 3 has the same structure as the multilayer substrate 101 according to the second embodiment, except for the shape of the intermetallic compound.

In the multilayer substrate 201 shown in FIG. 3, the shape of an intermetallic compound 261 is such that the surface in contact with the first electrode 31 is flat.

When the intermetallic compound 261 has such a shape, the contact area between the first electrode 31 and the intermetallic compound 261 can be increased, similarly to the multilayer substrate 101. Therefore, the physical connection stability and electrical conductivity between the first electrode 31 and the interlayer connection conductor 50 can be improved.

### Third Embodiment

Next, a multilayer substrate according to a third embodiment of the present disclosure is described.

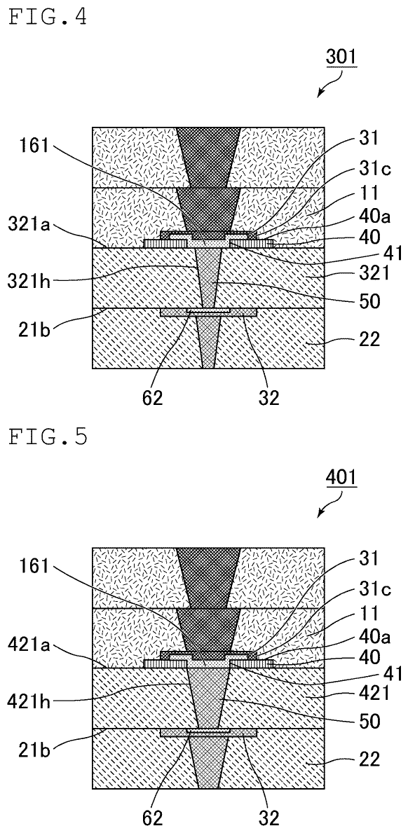

FIG. 4 is a schematic cross-sectional view of an example of an interlayer connection conductor and its surroundings of the multilayer substrate according to the third embodiment of the present disclosure.

A multilayer substrate 301 according to the third embodiment of the present disclosure shown in FIG. 4 has the same structure as the multilayer substrate 101 according to the second embodiment, except for the sizes of the openings of the via hole 21h in the first thermoplastic resin layer 21.

In the multilayer substrate 301 shown in FIG. 4, the area of the opening of a via hole 321h in a first main surface 321a of a first thermoplastic resin layer 321 is smaller than the contact area between the intermetallic compound 161 and the first electrode 31.

In the production of the multilayer substrate of the present disclosure, the first electrode is brought into contact with a conductive paste that is a precursor of the interlayer connection conductor, and the conductive paste is melted and then solidified to form the interlayer connection conductor. The first electrode and the interlayer connection conductor are connected by transient liquid phase diffusion bonding. In the transient liquid phase diffusion bonding, the liquid phase flows and covers the entire exposed surface of the first electrode 31.

Thus, the intermetallic compound 161 is formed on the entire exposed surface of the first electrode 31.

Therefore, in the multilayer substrate 301, no gap occurs between the first electrode 31 and the first thermoplastic resin layer 321, and the physical connection stability and electrical conductivity between the first electrode 31 and the interlayer connection conductor 50 can be sufficiently increased.

### Fourth Embodiment

Next, a multilayer substrate according to a fourth embodiment of the present disclosure is described.

FIG. 5 is a schematic cross-sectional view of an example of an interlayer connection conductor and its surroundings of the multilayer substrate according to the fourth embodiment of the present disclosure.

A multilayer substrate 401 according to the fourth embodiment of the present disclosure shown in FIG. 5 has the same structure as the multilayer substrate 101 according to the second embodiment, except for the sizes of the openings of the via hole 21h in the first thermoplastic resin layer 21.

In the multilayer substrate 401 shown in FIG. 5, the area of the opening of a via hole 421h in a first main surface 421a of a first thermoplastic resin layer 421 is the same as the area of the opening of the protective layer 40.

Even in such an embodiment, the physical connection stability and electrical conductivity between the first electrode 31 and the interlayer connection conductor 50 can be sufficiently increased.

### Another Embodiment

In the multilayer substrate of the present disclosure, when the protective layer is made of a ceramic material, pores are formed in the protective layer.

When the first electrode and the interlayer connection conductor are connected by transient liquid phase diffusion bonding, the liquid phase may enter the pores in the protective layer. Such an embodiment is described with reference to the drawing.

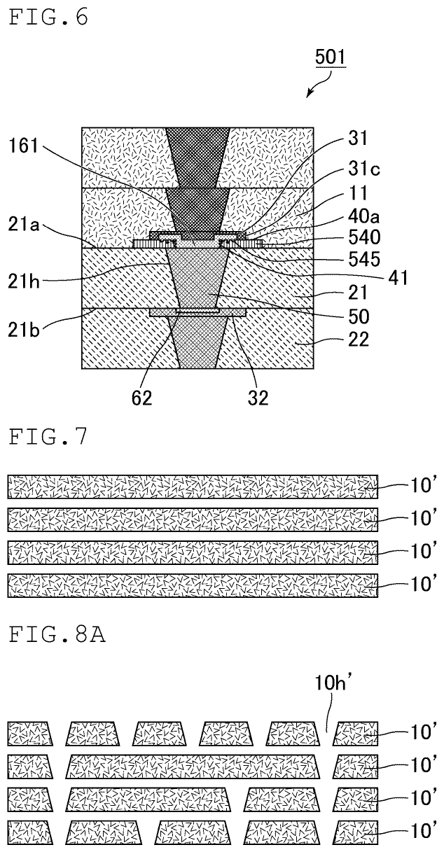

FIG. 6 is a schematic cross-sectional view of an example of an interlayer connection conductor and its surroundings of a multilayer substrate according to another embodiment of the present disclosure.

A multilayer substrate 501 shown in FIG. 6 has the same structure as the multilayer substrate 101, except that a protective layer 540 is made of a ceramic material and part of the intermetallic compound 161 enters a pore 545 of the protective layer 540.

The present disclosure encompasses such a multilayer substrate according to such another embodiment.

### <Method of Producing Multilayer Substrate>

Next, a method of producing the multilayer substrate of the present disclosure is described. The following describes the case where the ceramic layers include an LTCC material.

### Fifth Embodiment

### <Preparation of LTCC Green Sheet>

FIG. 7 is a schematic process diagram of an example

of preparing LTCC green sheets in a method of producing a multilayer substrate according to a fifth embodiment of the present disclosure.

In the production of the multilayer substrate according to the first embodiment of the present disclosure, first, as shown in FIG. 7, multiple LTCC green sheets 10′ are prepared.

The LTCC green sheets 10′ can be prepared in the following manner.

First, a ceramic powder, a binder, and a plasticizer are mixed in any amounts to prepare a slurry. The ceramic powder may include any of the materials described for the ceramic layer 10. The binder and the plasticizer may each be a conventionally known one.

Next, the slurry is applied to carrier films and formed into sheets to obtain the LTCC green sheets 10′.

The slurry may be applied with a lip coater or a doctor blade. In this case, the thickness of each LTCC green sheet 10′ is preferably, for example, 5 μm to 100 μm.

### <Filling of via Hole of LTCC Green Sheet>

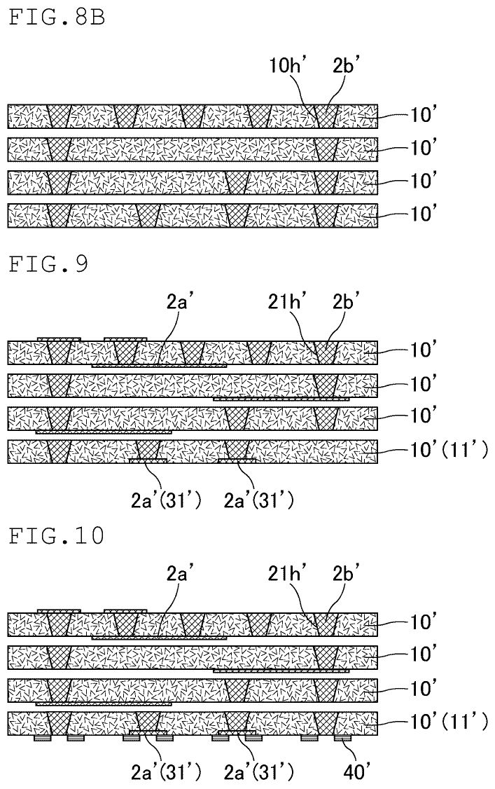

FIG. 8A and FIG. 8B are each a schematic process diagram of an example of filling via holes of the LTCC green sheets in the method of producing the multilayer substrate according to the fifth embodiment of the present disclosure.

Next, as shown in FIG. 8A, via holes 10h′ are formed in the LTCC green sheets 10′. The via holes 10h′ may be formed by any method and can be formed using a mechanical punch, a CO₂ laser, a UV laser, or the like.

The sizes of the openings of each via hole 10h′ are not limited, and are each preferably 20 μm to 200 μm.

Next, as shown in FIG. 8B, the via holes 10h′ are filled with a conductive paste 2b′ containing a conductive powder, a plasticizer, and a binder.

The conductive paste 2b′ may contain the ceramic powder of the LTCC green sheets 10′. When the conductive paste 2b′ contains such a ceramic powder, the difference in shrinkage between the LTCC green sheets 10′ and the conductive paste 2b′ is small. As a result, cracking and the like can be prevented from occurring during firing of the LTCC green sheets 10′ and the conductive paste 2b′.

### <Formation of Electrode Pattern on LTCC Green Sheet>

FIG. 9 is a schematic process diagram of an example of forming electrode patterns on the LTCC green sheets in the method of producing the multilayer substrate according to the fifth embodiment of the present disclosure.

Next, as shown in FIG. 9, electrode patterns 2a′ are printed on the surfaces of the LTCC green sheets 10′ using a conductive paste containing a conductive powder, a plasticizer, and a binder. Examples of the printing method include screen printing, inkjet printing, and gravure printing.

The conductive paste forming the electrode patterns 2a′ may contain the ceramic powder of the LTCC green sheets 10′. When the conductive paste forming the electrode patterns 2a′ contains such a ceramic powder, the difference in shrinkage between the LTCC green sheets 10′ and the electrode patterns 2a′ is small. As a result, cracking and the like can be prevented from occurring during firing of the LTCC green sheets 10′ and the electrode patterns 2a′.

In a later step, the LTCC green sheets 10′ are laminated to form a laminate. Among the electrode patterns 2a′ on the outermost LTCC green sheet 10′ in the laminate, one or more of the electrode patterns (indicated by the symbol 31′ in FIG. 9) serve as the first electrodes connected to the interlayer connection conductors in the multilayer substrate to be produced.

Furthermore, the LTCC green sheet 10′ on which the electrode patterns 31′ are formed serves as the ceramic substrate in contact with the first main surface of the first thermoplastic resin layer in the multilayer substrate to be produced.

### <Application of Protective Layer Paste Containing Ceramic Material>

FIG. 10 is a schematic process diagram of an example of applying a protective layer paste containing a ceramic material in the method of producing the multilayer substrate according to the fifth embodiment of the present disclosure.

Next, as shown in FIG. 10, a protective layer paste 40′ is applied to the outlines of the electrode patterns 31′.

The protective layer paste 40′ is preferably made of the same material as the LTCC green sheets 10′.

When the protective layer paste 40′ and the LTCC green sheets 10′ are made of the same material, they have the same shrinkage rate during firing. This can prevent cracking from occurring during firing of the protective layer paste 40′ and the LTCC green sheets 10′.

The thickness of the protective layer paste 40′ is preferably 2 μm to 10 μm.

If the thickness of the protective layer paste is less than 2 μm, a first electrode likely to peel off is formed in a later step.

If the thickness of the protective layer paste is more than 10 μm, a thick protective layer is formed in a later step. Therefore, in a later step, the protective layer hinders the lamination of the first thermoplastic resin layer and the ceramic layer, and a gap is likely to occur between the interlayer connection conductor and the first electrode.

If the thickness of the protective layer paste is more than 10 μm, a thick protective layer is formed in a later step. Therefore, the liquid phase is less likely to flow over the protective layer in the formation of an intermetallic compound in a later step. Thus, the intermetallic compound is less likely to be in contact with an inner end side area of the covering surface of the protective layer.

The protective layer paste 40′ preferably covers an area of 30 μm to 100 μm inward from the outline of the electrode pattern 31′.

The formation of the protective layer paste 40′ in such an area can prevent peeling off of the first electrode 31 to be formed in a later step.

### <Lamination of LTCC Green Sheet>

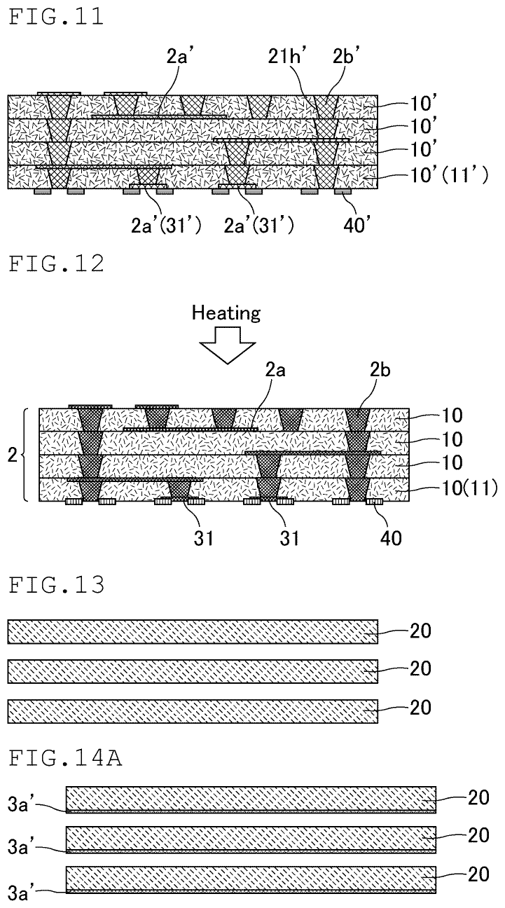

FIG. 11 is a schematic process diagram of an example of laminating the LTCC green sheets in the method of producing the multilayer substrate according to the fifth embodiment of the present disclosure.

Next, as shown in FIG. 11, the LTCC green sheets 10′ are laminated to form an LTCC green sheet laminate 2′. The number of the sheets to be laminated is preferably determined appropriately according to the design of the multilayer substrate.

Thereafter, the LTCC green sheet laminate 2′ is placed in a mold and pressure-bonded. The pressure and temperature are preferably set freely according to the design of the multilayer substrate.

### <Firing of LTCC Green Sheet Laminate>

FIG. 12 is a schematic process diagram of an example of firing an LTCC green sheet laminate in the method of producing the multilayer substrate according to the fifth embodiment of the present disclosure.

Next, as shown in FIG. 12, the LTCC green sheet laminate 2′ is heated and fired to form the multilayer ceramic layer 2.

In this step, the conductive paste 2b′ is fired into the vias 2b, and the electrode patterns 2a′ are fired into the electrode patterns 2a and the first electrodes 31.

The firing may be performed using a firing furnace such as a batch furnace or a belt furnace. The firing may be performed under any conditions and is preferably performed at 850° C. or higher and 1050° C. or lower for 60 minutes to 180 minutes.

When the conductive paste 2b′ and the electrode patterns 2a′ contain copper (Cu), the firing is preferably performed in a reducing atmosphere.

### <Preparation of Thermoplastic Resin Layer>

FIG. 13 is a schematic process diagram of an example of preparing thermoplastic resin layers in the method of producing the multilayer substrate according to the fifth embodiment of the present disclosure.

Next, as shown in FIG. 13, the sheet-like thermoplastic resin layers 20 are prepared. The preferred materials of the thermoplastic resin layers 20 have already been described and are thus omitted here.

The thickness of each thermoplastic resin layer 20 is preferably 10 μm to 100 μm.

### <Formation of Electrode Pattern on Thermoplastic Resin Layer>

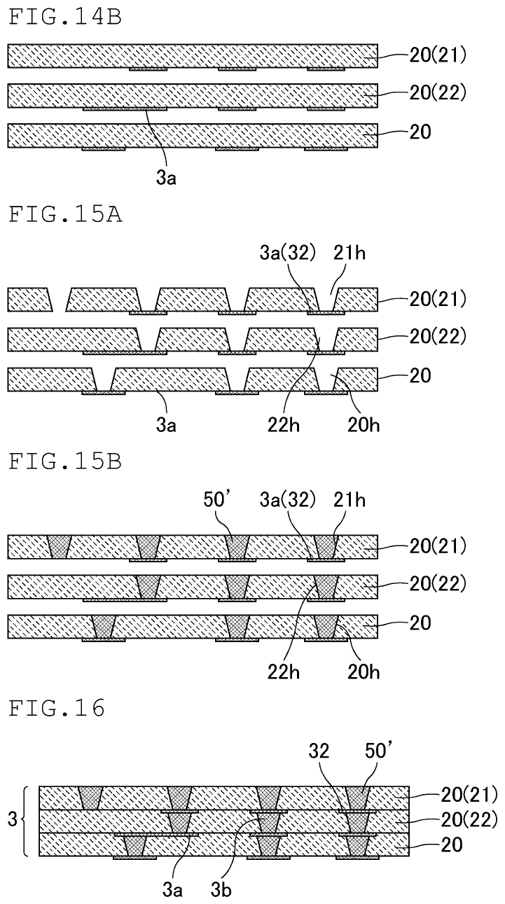

FIG. 14A and FIG. 14B are each a schematic process

diagram of an example of forming electrode patterns on the thermoplastic resin layers in the method of producing the multilayer substrate according to the fifth embodiment of the present disclosure.

Next, as shown in FIG. 14A, a metal foil 3a′ is laminated on the main surfaces of the thermoplastic resin layers 20. Next, as shown in FIG. 14B, the metal foil 3a′ is patterned by etching or the like to form the electrode patterns 3a.

The metal foil 3a′ may be made of copper (Cu), silver (Ag), aluminum (Al), nickel (Ni), stainless steel (SUS), or an alloy of any of these.

Preferably, the metal foil 3a′ has a shiny surface as one main surface and a matte surface as the other surface. The metal foil 3a′ is preferably laminated such that the matte surface is in contact with the main surface of each thermoplastic resin layer 20.

The matte surface of the metal foil 3a′ is subjected to roughening treatment, and preferably has a surface roughness Rz (JIS B 0601-2001) of 1 μm to 15 μm.

In a later step, the thermoplastic resin layers 20 are laminated to form a laminate. The outermost thermoplastic resin layer 20 in the laminate serves as the first thermoplastic resin layer 21. Another thermoplastic resin layer 20 in contact with the second main surface 21b of the first thermoplastic resin layer 21 serves as the second thermoplastic resin layer 22.

Among the electrode patterns 3a on the main surface of the second thermoplastic resin layer 22 facing the second main surface 21b, one or more of the electrode patterns serve as the second electrodes 32 connected to the interlayer connection conductors in the multilayer substrate to be produced.

### <Filling of via Hole of Thermoplastic Resin Layer>

FIG. 15A and FIG. 15B are each a schematic process diagram of an example of filling via holes of the thermoplastic resin layers in the method of producing the multilayer substrate according to the fifth embodiment of the present disclosure.

Next, as shown in FIG. 15A, the via holes 21h, via

holes 22h, and via holes 20h are formed in the first thermoplastic resin layer 21, the second thermoplastic resin layer 22, and another thermoplastic resin layer 20, respectively.

The via holes may be formed by any method and can be formed using a mechanical punch, a CO₂ laser, a UV laser, or the like.

After the via holes are formed, a desmear treatment is preferably performed by an oxygen plasma treatment, a corona discharge treatment, or a potassium permanganate treatment.

The sizes of the openings of each of the via holes 21h, 22h, and 20h are not limited, and are each preferably 20 μm to 200 μm.

For the convenience of showing the internal structure in a plan view, FIG. 15A includes a portion in which a via hole is formed directly under the electrode pattern 3a and the via hole does not appear to be formed as a through hole. However, actually, the positions where the electrode patterns 3a are formed and the positions where the via holes are formed are shifted in the depth direction of cross-section, and the via holes are formed as through holes.

Next, as shown in FIG. 15B, the via holes 21h, 22h and 20h are filled with a conductive paste 50′ that is a precursor of the interlayer connection conductor.

The filling may be performed by any method, and can be performed by screen printing, vacuum printing, or the like.

The conductive paste 50′ contains a first metal powder and a second metal powder having a melting point higher than that of the first metal powder.

Preferably, the first metal powder in the conductive paste 50′ is made of Sn or a Sn alloy and the second metal powder in the conductive paste 50′ is made of a Cu—Ni alloy or a Cu—Mn alloy. The conductive paste 50′ may be, for example, a conductive paste disclosed in JP 5146627 B. Hereinafter, the metal component in the first metal powder is also referred to as a “first metal”, and the metal component in the second metal powder is also referred to as a “second metal”.

Examples of the Sn or Sn alloy include a simple substance of Sn and alloys containing Sn and at least one selected from the group consisting of Cu, Ni, Ag, Au, Sb, Zn, Bi, In, Ge, Al, Co, Mn, Fe, Cr, Mg, Mn, Pd, Si, Sr, Te, and P. The Sn content of the Sn alloy is preferably 70 wt % or more, more preferably 85 wt % or more.

The proportion of Ni in the Cu—Ni alloy is preferably 10 wt % to 15 wt %. The proportion of Mn in the Cu—Mn alloy is preferably 10 wt % to 15 wt %. This enables supply of a necessary and sufficient amount of Ni or Mn to produce a desired intermetallic compound. When the proportion of Ni in the Cu—Ni alloy and the proportion of Mn in the Cu—Mn alloy are each less than 10 wt %, a portion of Sn tends to remain unreacted without being entirely converted into an intermetallic compound. Also when the proportion of Ni in the Cu—Ni alloy and the proportion of Mn in the Cu—Mn alloy are each more than 15 wt %, a portion of Sn tends to remain unreacted without being entirely converted into an intermetallic compound.

The Cu—Ni alloy or the Cu—Mn alloy may contain both Mn and Ni or may contain a third component such as P.

The first metal powder and the second metal powder each preferably have an arithmetic mean particle size of 3 μm to 10 μm. When the mean particle size of each metal powder is too small, the production cost increases. In addition, such a metal powder tends to be oxidized quickly and interfere with a reaction. In contrast, when the mean particle size of each metal powder is too large, it is difficult to fill each via hole with the conductive paste 50′.

The proportion of the second metal in the metal components in the conductive paste 50′ is preferably 30 wt % or more. In other words, the proportion of the first metal in the metal components in the conductive paste 50′ is preferably 70 wt % or less. In this case, the residual proportion of the first metal such as Sn is further decreased, allowing for an increase in the proportion of the intermetallic compound.

The proportion of the metal components in the conductive paste 50′ is preferably 70 wt % to 95 wt %. When the proportion of the metal components is more than 95 wt %, it is difficult to obtain a low-viscosity conductive paste 50′ having excellent filling properties. In contrast, when the proportion of the metal components is less than 70 wt %, a flux component tends to remain.

The conductive paste 50′ preferably contains a flux component. The flux component may be any of various known flux components used as materials of common conductive pastes, and contains a resin. Examples of components other than the resin include vehicles, solvents, thixotropic agents, and activators.

The resin preferably includes at least one thermosetting resin selected from the group consisting of epoxy resins, phenolic resins, polyimide resins, silicone resins or modified resins thereof, and acrylic resins, or at least one thermoplastic resin selected from the group consisting of polyamide resins, polystyrene resins, polymethacrylic resins, polycarbonate resins, and cellulose-based resins.

Examples of the vehicles include rosin-based resins and synthetic resins, which are obtained from rosin and rosin derivatives such as modified rosins or the like, and mixtures thereof. Examples of the rosin-based resins obtained from rosin and rosin derivatives such as modified rosins include gum rosin, tall rosin, wood rosin, polymerized rosin, hydrogenated rosin, formylated rosin, rosin ester, rosin-modified maleic acid resin, rosin-modified phenolic resin, rosin-modified alkyd resin, and other various rosin derivatives. Examples of the synthetic resins obtained from rosin and rosin derivatives such as modified rosins include polyester resins, polyamide resins, phenoxy resins, and terpene resins.

Examples of the solvents include alcohols, ketones, esters, ethers, and aromatic hydrocarbons. Specific examples include benzyl alcohol, ethanol, isopropyl alcohol, butanol, diethylene glycol, ethylene glycol, glycerol, ethyl cellosolve, butyl cellosolve, ethyl acetate, butyl acetate, butyl benzoate, diethyl adipate, dodecane, tetradecene, α-terpineol, terpineol, 2-methyl-2, 4-pentanediol, 2-ethylhexanediol, toluene, xylene, propylene glycol monophenyl ether, diethylene glycol monohexyl ether, ethylene glycol monobutyl ether, diethylene glycol monobutyl ether, diisobutyl adipate, hexylene glycol, cyclohexane dimethanol, 2-terpinyloxy ethanol, 2-dihydroterpinyloxy ethanol, and mixtures thereof. Preferred among these are terpineol, ethylene glycol monobutyl ether, diethylene glycol monoethyl ether, and diethylene glycol monobutyl ether.

Specific examples of the thixotropic agents include hydrogenated castor oil, carnauba wax, amides, hydroxy fatty acids, dibenzylidene sorbitol, bis(p-methylbenzylidene)sorbitol, beeswax, stearamide, and ethylenebisamide hydroxystearate. The thixotropic agents can also be those thixotropic agents to which the following additives are added as needed: fatty acids such as caprylic acid, lauric acid, myristic acid, palmitic acid, stearic acid, and behenic acid; hydroxy fatty acids such as 1,2-hydroxystearic acid; antioxidants; surfactants; and amines.

Examples of the activators include amine hydrohalides, organohalogen compounds, organic acids, organic amines, and polyhydric alcohols.

Examples of the amine hydrohalides include diphenylguanidine hydrobromide, diphenylguanidine hydrochloride, cyclohexylamine hydrobromide, ethylamine hydrochloride, ethylamine hydrobromide, diethylaniline hydrobromide, diethylaniline hydrochloride, triethanolamine hydrobromide, and monoethanolamine hydrobromide.

Examples of the organohalogen compounds include chlorinated paraffins, tetrabromoethane, dibromopropanol, 2,3-dibromo-1,4-butanediol, 2,3-dibromo-2-butene-1,4-diol, and tris(2,3-dibromopropyl)isocyanurate.

Examples of the organic acids include malonic acid, fumaric acid, glycolic acid, citric acid, malic acid, succinic acid, phenyl succinic acid, maleic acid, salicylic acid, anthranilic acid, glutaric acid, suberic acid, adipic acid, sebacic acid, stearic acid, abietic acid, benzoic acid, trimellitic acid, pyromellitic acid, and dodecanoic acid.

Examples of the organic amines include monoethanolamine, diethanolamine, triethanolamine, tributylamine, aniline, and diethylaniline.

Examples of the polyhydric alcohols include erythritol, pyrogallol, and ribitol.

### <Lamination of Thermoplastic Resin Layer>

FIG. 16 is a schematic process diagram of an example of laminating the thermoplastic resin layers in the method of producing the multilayer substrate according to the fifth embodiment of the present disclosure.

Next, as shown in FIG. 16, the first thermoplastic resin layer 21, the second thermoplastic resin layer 22, and the another thermoplastic resin layer 20 are laminated to form the multilayer thermoplastic resin layer 3.

### <Lamination of Multilayer Ceramic Layer and Multilayer Thermoplastic Resin Layer>

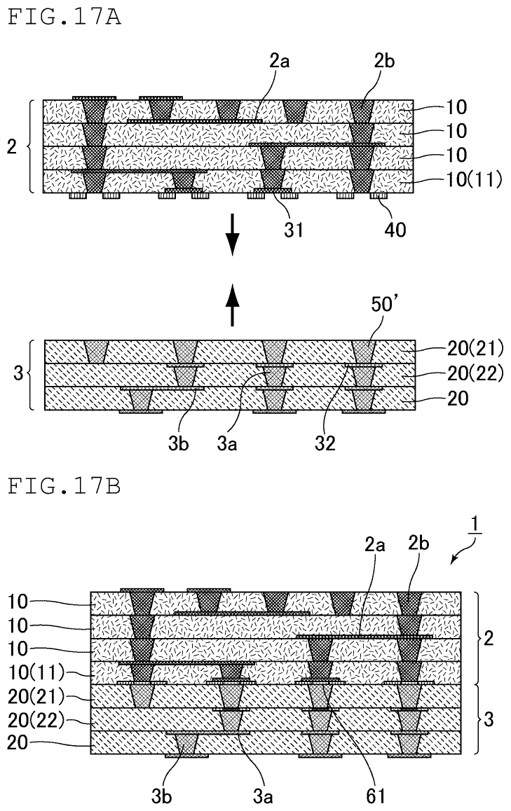

FIG. 17A and FIG. 17B are each a schematic process diagram of an example of laminating the multilayer ceramic layer and the multilayer thermoplastic resin layer in the method of producing the multilayer substrate according to the fifth embodiment of the present disclosure.

Next, as shown in FIG. 17A, the multilayer ceramic layer 2 is laminated on the multilayer thermoplastic resin layer 3. The multilayer thermoplastic resin layer 3 and the multilayer ceramic layer 2 are positioned so that the conductive paste 50′ in the first thermoplastic resin layer 21 of the multilayer thermoplastic resin layer 3 is in contact with the exposed surfaces of the first electrodes 31 on the outermost ceramic layer 11 of the multilayer ceramic layer 2.

Thereafter, as shown in FIG. 17B, the multilayer thermoplastic resin layer 3 and the multilayer ceramic layer 2 are integrated by application of pressure and heat.

The first thermoplastic resin layer 21 conforms to the irregularities on the surface of the ceramic layer 11 so that the multilayer thermoplastic resin layer 3 and the multilayer ceramic layer 2 are closely attached to each other owing to the anchor effect.

This step is performed by treatment at 230° C. or higher and 350° C. or lower under atmospheric pressure, for example.

In this step, the conductive paste 50′ is melted and then solidified to become the interlayer connection conductors 50.

The interlayer connection conductors 50 and the first electrodes 31 are connected by transient liquid phase diffusion bonding. At this time, the intermetallic compound 61 is formed between the interlayer connection conductors 50 and the first electrodes 31.

The transient liquid phase diffusion bonding is described with reference to the drawings.

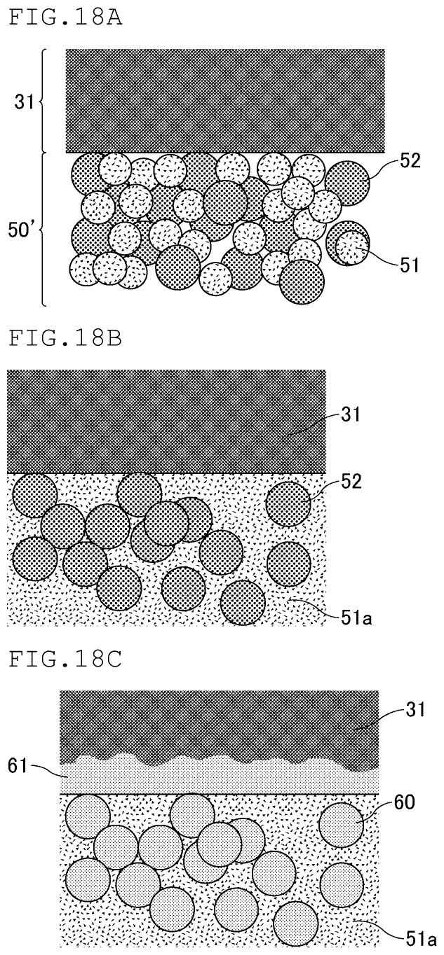

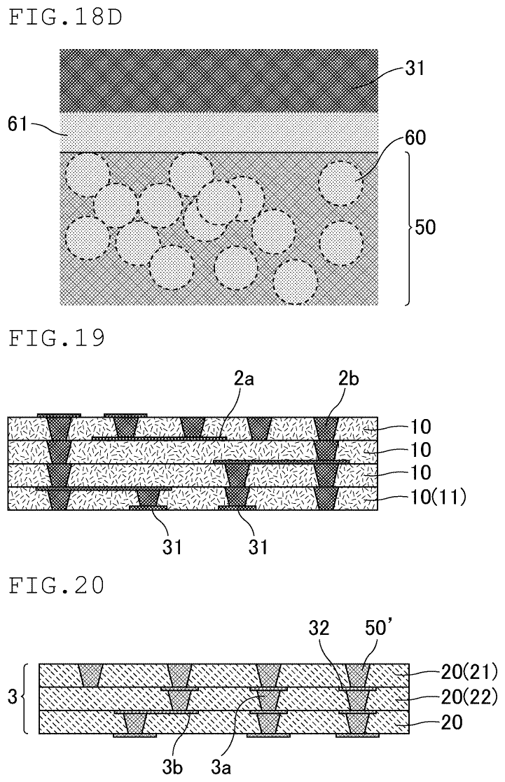

FIG. 18A to FIG. 18D are each an explanatory schematic diagram of an example of the connection between an interlayer connection conductor and a first electrode by transient liquid phase diffusion bonding.

As shown in FIG. 18A, the conductive paste 50′ contains a first metal powder 51 and a second metal powder 52 having a melting point higher than that of the first metal powder 51. The conductive paste 50′ is in contact with the first electrode 31.

As shown in FIG. 18B, when the conductive paste 50′ is heated in this state and reaches the melting point of the first metal powder 51, the first metal powder 51 melts and becomes a liquid phase first metal 51a.

Thereafter, as heat is continued to be applied, the liquid phase first metal 51a reacts with the second metal powder 52 to form the intermetallic compound 60, as shown in FIG. 18C.

Moreover, the liquid phase first metal 51a spreads in a diffusive manner over the first electrode 31, and reacts with the metal of the first electrode 31 to form the intermetallic compound 61.

Thereafter, when the heating is terminated and the temperature is lowered, the liquid phase first metal 51a solidifies to become the interlayer connection conductor 50, as shown in FIG. 18D. In FIG. 18D, for the sake of convenience, the outline of the intermetallic compound 60 derived from the second metal powder 52 is shown by a dashed line, but actually, the boundary is not clear and the intermetallic compound 60 does not appear to be particulate.

In this step, the interlayer connection conductor and the second electrode are connected by transient liquid phase diffusion bonding, so that an intermetallic compound is also formed between the interlayer connection conductor and the second electrode.

The multilayer substrate 1 can be produced through the above steps.

In the production of the multilayer substrate of the present disclosure, the intermetallic compound can be formed to have any of the shapes shown in FIGS. 2 to 6 by adjusting the composition of the conductive paste 50′, the composition and thickness of the first electrode 31, the thickness of the protective layer 40, and the pressure applied and the heating temperature in the lamination of the multilayer ceramic layer and the multilayer thermoplastic resin layer.

In other words, these adjustments allow part of the intermetallic compound to be in contact with the inner end side area of the covering surface of the protective layer and to be continuous with the intermetallic compound formed between the interlayer connection conductor and the first electrode.

Electronic components such as IC chips and SMD components can be mounted on the produced multilayer substrate 1 by a reflow process or the like. After the reflow process, the multilayer substrate 1 on which the electronic components are mounted may be cleaned and molded with resin. Furthermore, the molded multilayer substrate 1 may be cut into pieces by dicer cutting, laser cutting, or the like. Thereafter, a shielding film may be formed on the surface of the molding resin of the pieces.

### Sixth Embodiment

Next, another method of producing the multilayer substrate of the present disclosure is described. The following describes the case where the ceramic layers include an LTCC material.

A method of producing a multilayer substrate according to a sixth embodiment of the present disclosure is the same as the method of producing the multilayer substrate according to the fifth embodiment of the present disclosure, except that the section <Application of protective layer paste containing ceramic material> described above is not performed, and the section <Disposing of protective layer including thermoplastic resin> described below is performed after the section <Filling of via hole of thermoplastic resin layer> described above.

The method of producing the multilayer substrate according to the sixth embodiment of the present disclosure is described in detail below with reference to the drawings.

### <Preparation of Multilayer Ceramic Layer>

FIG. 19 is a schematic cross-sectional view of an example of a multilayer ceramic layer prepared in the method of producing the multilayer substrate according to the sixth embodiment of the present disclosure.

A multilayer ceramic layer 602 as shown in FIG. 19 is produced by performing the following steps in the method of producing the multilayer substrate according to the fifth embodiment of the present disclosure in the following order: <Preparation of LTCC green sheet>, <Filling of via hole of LTCC green sheet>, <Formation of electrode pattern on LTCC green sheet>, <Lamination of LTCC green sheet>, and <Firing of LTCC green sheet laminate>.

The multilayer ceramic layer 602 has the same structure as the multilayer ceramic layer 2, except that the multilayer ceramic layer 602 is free from the protective layer 40.

### <Preparation of Multilayer Thermoplastic Resin Layer>

FIG. 20 is a schematic cross-sectional view of an example of a multilayer thermoplastic resin layer prepared in the method of producing the multilayer substrate according to the sixth embodiment of the present disclosure.

The multilayer thermoplastic resin layer 3 is prepared by performing the following steps in the method of producing the multilayer substrate according to the fifth embodiment of the present disclosure: <Preparation of thermoplastic resin layer>, <Formation of electrode pattern on thermoplastic resin layer>, <Filling of via hole of thermoplastic resin layer>, and <Lamination of thermoplastic resin layer>.

### <Disposing of Protective Layer Including Thermoplastic Resin>

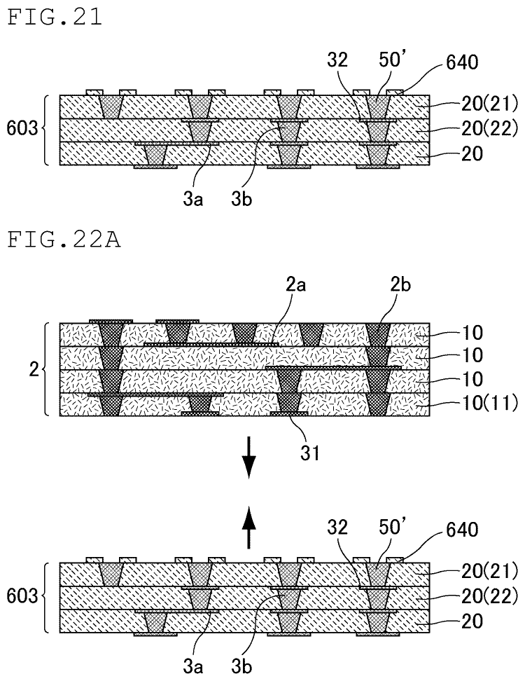

FIG. 21 is a schematic process diagram of an example of disposing protective layers including a thermoplastic resin in the method of producing the multilayer substrate according to the sixth embodiment of the present disclosure.

Next, protective layers 640 including a thermoplastic resin are formed on the first thermoplastic resin layer 21 of the multilayer thermoplastic resin layer 3 to prepare a multilayer thermoplastic resin layer 603.

The protective layers 640 are preferably made of the same material as the thermoplastic resin layers 20.

Furthermore, the protective layers 640 are formed in positions such that they cover the outlines of the first electrodes 31 on the multilayer ceramic layer 602 when the section <Lamination of multilayer ceramic layer and multilayer thermoplastic resin layer> described below is performed. The positions can be determined in advance by designing the multilayer substrate.

### <Lamination of Multilayer Ceramic Layer and Multilayer Thermoplastic Resin Layer>

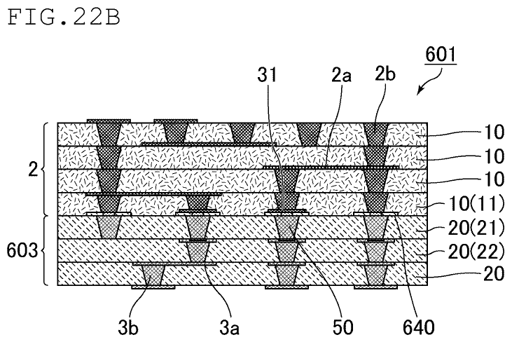

FIG. 22A and FIG. 22B are each a schematic process

diagram of an example of laminating the multilayer ceramic layer and the multilayer thermoplastic resin layer in the method of producing the multilayer substrate according to the sixth embodiment of the present disclosure.

Next, as shown in FIG. 22A, the multilayer ceramic layer 2 is laminated on the multilayer thermoplastic resin layer 603. The multilayer thermoplastic resin layer 603 and the multilayer ceramic layer 602 are positioned so that the conductive paste 50′ in the first thermoplastic resin layer 21 of the multilayer thermoplastic resin layer 603 is in contact with the exposed surface of the first electrodes 31 on the outermost ceramic layer 11 of the multilayer ceramic layer 602.

Thereafter, as shown in FIG. 22B, the multilayer thermoplastic resin layer 603 and the multilayer ceramic layer 602 are integrated by application of pressure and heat.

A multilayer substrate 601 in which the protective layers 640 include a thermoplastic resin can be produced through the above steps.

The present description discloses the followings.

Disclosed item (1) relates to a multilayer substrate including: a first thermoplastic resin layer including a first main surface, a second main surface opposite to the first main surface, and a via hole penetrating from the first main surface to the second main surface; a ceramic layer in contact with the first main surface of the first thermoplastic resin layer; a second thermoplastic resin layer in contact with the second main surface of the first thermoplastic resin layer; a first electrode on a surface of the ceramic layer in contact with the first main surface of the first thermoplastic resin layer; a protective layer covering at least part of an outline of the first electrode; a second electrode on a surface of the second thermoplastic resin layer in contact with the second main surface of the first thermoplastic resin layer; an interlayer connection conductor in the via hole and connecting the first electrode and the second electrode; and an intermetallic compound between the interlayer connection conductor and the first electrode.

Disclosed item (2) relates the multilayer substrate according to the disclosed item (1), wherein the protective layer includes an inner end inside the outline of the first electrode and a covering surface in contact with the first electrode to cover at least part of the outline of the first electrode, and part of the intermetallic compound is in contact with an inner end side portion of the covering surface of the protective layer and is continuous with the intermetallic compound between the interlayer connection conductor and the first electrode.

Disclosed item (3) relates to the multilayer substrate according to the disclosed item (1) or (2), wherein the protective layer is made of a same material as that of the ceramic layer.

Disclosed item (4) relates to the multilayer substrate according to any one of the disclosed items (1) to (3), wherein the protective layer is made of a same material as that of the first thermoplastic resin layer.

Disclosed item (5) relates to the multilayer substrate according to any one of the disclosed items (1) to (4), wherein part of the protective layer is inside an opening of the via hole in the first main surface, and the part of the protective layer inside the opening of the via hole is in contact with the interlayer connection conductor.

### REFERENCE SIGNS LIST

1, 101, 201, 301, 401, 501, 601 multilayer substrate
2, 602 multilayer ceramic layer
2′ LTCC green sheet laminate
2a, 2a′, 3a electrode pattern
2b, 3b via
2b′, 50′ conductive paste
3, 603 multilayer thermoplastic resin layer
3a′ metal foil
10, 11 ceramic layer
10′ LTCC green sheet
10h′, 21h, 22h, 321h, 421h via hole
20 thermoplastic resin layer
21, 321, 421 first thermoplastic resin layer

21a, 321a, 421a first main surface of first thermoplastic resin layer
21b second main surface of first thermoplastic resin layer
22 second thermoplastic resin layer
31 first electrode
31′ electrode pattern
31c outline of first electrode
32 second electrode
40, 540, 640 protective layer
40′ protective layer paste
40a: covering surface of protective layer
41 inner end of protective layer
50 interlayer connection conductor
51 first metal powder
51a liquid phase first metal
52 second metal powder
60, 61, 62, 161, 261 intermetallic compound
161a part of intermetallic compound
545 pore

1. A multilayer substrate comprising:
a first thermoplastic resin layer including a first main surface, a second main surface opposite to the first main surface, and a via hole penetrating from the first main surface to the second main surface;
a ceramic layer in contact with the first main surface of the first thermoplastic resin layer;
a second thermoplastic resin layer in contact with the second main surface of the first thermoplastic resin layer;
a first electrode on a surface of the ceramic layer in contact with the first main surface of the first thermoplastic resin layer;
a protective layer covering at least part of an outline of the first electrode;
a second electrode on a surface of the second thermoplastic resin layer in contact with the second main surface of the first thermoplastic resin layer;
an interlayer connection conductor in the via hole and connecting the first electrode and the second electrode; and
an intermetallic compound between the interlayer connection conductor and the first electrode.

2. The multilayer substrate according to claim 1,
wherein the protective layer includes an inner end inside the outline of the first electrode and a covering surface in contact with the first electrode to cover at least part of the outline of the first electrode, and
part of the intermetallic compound is in contact with an inner end side portion of the covering surface of the protective layer and is continuous with the intermetallic compound between the interlayer connection conductor and the first electrode.

3. The multilayer substrate according to claim 1, wherein the protective layer is made of a same material as that of the ceramic layer.

4. The multilayer substrate according to claim 1, wherein the protective layer is made of a same material as that of the first thermoplastic resin layer.

5. The multilayer substrate according to claim 1, wherein part of the protective layer is inside an opening of the via hole in the first main surface, and the part of the protective layer inside the opening of the via hole is in contact with the interlayer connection conductor.

6. The multilayer substrate according to claim 1, wherein the intermetallic compound is a first intermetallic compound, and the multilayer substrate further comprises a second intermetallic compound between the interlayer connection conductor and the second electrode.

7. The multilayer substrate according to claim 1, wherein the via hole has a tapered shape in which an opening in the first main surface is larger than an opening in the second main surface.

8. The multilayer substrate according to claim 1, wherein a thickness of the protective layer is 2 μm to 10 μm.

9. The multilayer substrate according to claim 1, wherein the protective layer covers an area of 30 μm to 100 μm inward from the outline of the first electrode.

10. The multilayer substrate according to claim 1, wherein an area of an opening of the via hole in the first main surface of the first thermoplastic resin layer is smaller than a contact area between the intermetallic compound and the first electrode.

11. The multilayer substrate according to claim 1, wherein an area of an opening of the via hole in the first main surface of the first thermoplastic resin layer is the same as an area of an opening of the protective layer.

12. The multilayer substrate according to claim 1, wherein the protective layer is made of a ceramic material.

13. The multilayer substrate according to claim 12, wherein part of the intermetallic compound enters a pore of the protective layer.
